(19) United States
(12) Patent Application Publication
(10) Pub. No.: US 2026/0068457 A1
(43) Pub. Date: Mar. 5, 2026

(54) DISPLAY DEVICE, ELECTRONIC DEVICE, AND METHOD OF MANUFACTURING DISPLAY DEVICE

(71) Applicant: SAMSUNG DISPLAY CO., LTD., Yongin-si (KR)

(72) Inventors: Hyunju Choi, Yongin-si (KR); Sangwoo Kim, Yongin-si (KR); Dongbum Lee, Yongin-si (KR)

(21) Appl. No.: 19/262,574

(22) Filed: Jul. 8, 2025

(30) Foreign Application Priority Data
Sep. 2, 2024 (KR) 10-2024-0118802

(51) Int. Cl. H10K 59/131; H10K 59/12; H10K 59/95

(52) U.S. Cl. CPC H10K 59/131; H10K 59/1201; H10K 59/95

(57) ABSTRACT

A display device includes: a display panel; and a circuit film electrically connected to the display panel, wherein the display panel includes: a plurality of first pads, wherein some of the plurality of first pads extend in a first direction, wherein the plurality of first pads are arranged in a second direction different from the first direction; and a first alignment pad including a first portion extending in the first direction, and wherein the circuit film includes: a plurality of second pads, wherein some of the plurality of second pads extend in the first direction, wherein the plurality of second pads are arranged in the second direction; and a second alignment pad including a first portion extending in the first direction.

### CROSS-REFERENCE TO RELATED APPLICATION

This application claims priority under 35 U.S.C. §119 to Korean Patent Application No. 10-2024-0118802, filed on September 2, 2024, in the Korean Intellectual Property Office, the disclosure of which is incorporated by reference herein in its entirety.

### TECHNICAL FIELD

One or more embodiments of the present invention relate to a display device, an electronic device including the display device, and a method of manufacturing the display device. The display device according to an embodiment may include a light-emitting diode.

### DISCUSSION OF THE RELATED ART

Display devices may provide visual information in the form of still images and moving images to users. Typically, the display devices may include a substrate divided into a display area and a peripheral area. A scan line may be insulated from a data line in the display area, and a plurality of pixels may be arranged in the display area. A thin-film transistor and a pixel electrode electrically connected to the thin-film transistor may be provided in the display area, and both the thin-film transistor and the pixel electrode corresponds to a pixel of the plurality of pixels in the display area. In addition, an opposite electrode may be provided in the display area, and the opposite electrode may be commonly provided to the plurality of pixels. Various wirings, a scan driver, a data driver, a controller, a pad portion, and the like configured to transfer electrical signals to the display area may be provided in the peripheral area.

### SUMMARY

According to an embodiment of the present, a display device includes: a display panel; and a circuit film electrically connected to the display panel, wherein the display panel includes: a plurality of first pads, wherein some of the plurality of first pads extend in a first direction, wherein the plurality of first pads are arranged in a second direction different from the first direction; and a first alignment pad including a first portion extending in the first direction, and wherein the circuit film includes: a plurality of second pads, wherein some of the plurality of second pads extend in the first direction, wherein the plurality of second pads are arranged in the second direction; and a second alignment pad including a first portion extending in the first direction.

In an embodiment of the present invention, the first alignment pad includes a second portion crossing the first portion of the first alignment pad and extending in the second direction, and the second alignment pad includes a second portion crossing the first portion of the second alignment pad and extending in the second direction.

In an embodiment of the present invention, the first alignment pad and the second alignment pad overlap each other.

In an embodiment of the present invention, the plurality of first pads and the plurality of second pads overlap each other and are electrically connected to each other.

In an embodiment of the present invention, a length of the first portion of the first alignment pad in the first direction is equal to a length of at least one of the plurality of first pads in the first direction.

In an embodiment of the present invention, a width of each of the plurality of first pads in the second direction is greater than a width of each of the plurality of second pads in the second direction.

In an embodiment of the present invention, a width of the first portion of the first alignment pad in the second direction increases along the first direction, and a width of the first portion of the second alignment pad in the second direction increases along the first direction.

In an embodiment of the present invention, the display panel further includes a first dummy pad extending in the first direction and disposed between the first alignment pad and the plurality of first pads, and the circuit film further includes a second dummy pad extending in the first direction and disposed between the second alignment pad and the plurality of second pads, wherein the first dummy pad and the second dummy pad overlap each other.

In an embodiment of the present invention, at least some of the plurality of first pads are connected to each other.

In an embodiment of the present invention, the display panel further includes at least one third dummy pad adjacent to the first alignment pad and spaced apart from the first alignment pad and the plurality of first pads.

According to an embodiment of the present invention, a method of manufacturing a display device includes: aligning a display panel and a circuit film with each other; and bringing the display panel and the circuit film close to each other, wherein the display panel includes: a plurality of first pads, wherein some of the plurality of first pads extend in a first direction, wherein the plurality of first pads are arranged in a second direction different from the first direction; and a first alignment pad including a first portion extending in the first direction, and wherein the circuit film includes: a plurality of second pads, wherein some of the plurality of the second pads extend in the first direction, wherein the plurality of second pads are arranged in the second direction; and a second alignment pad including a first portion extending in the first direction, wherein, in the aligning of the display panel and the circuit film with each other, the first alignment pad and the second alignment pad are aligned with each other.

In an embodiment of the present invention, the first alignment pad includes a second portion crossing the first portion of the first alignment pad and extending in the second direction, and the second alignment pad includes a second portion crossing the first portion of the second alignment pad and extending in the second direction, and in the aligning of the display panel and the circuit film with each other, the first portion and the second portion of the first alignment pad are respectively aligned with the first portion and the second portion of the second alignment pad.

In an embodiment of the present invention, when the first alignment pad and the second alignment pad are aligned with each other, the plurality of first pads and the plurality of second pads overlap each other.

In an embodiment of the present invention, a length of the first portion of the first alignment pad in the first direction is equal to a length of at least one of the plurality of first pads in the first direction.

In an embodiment of the present invention, a width of each of the plurality of first pads in the second direction is greater than a width of each of the plurality of second pads in the second direction.

In an embodiment of the present invention, a width of the first portion of the first alignment pad in the second direction increases along the first direction, and a width of the first portion of the second alignment pad in the second direction increases along the first direction.

In an embodiment of the present invention, the display panel further includes a first dummy pad extending in the first direction and disposed between the first alignment pad and the plurality of first pads, and the circuit film further includes a second dummy pad extending in the first direction and disposed between the second alignment pad and the plurality of second pads, and when the first alignment pad and the second alignment pad are aligned with each other, the first dummy pad and the second dummy pad overlap each other.

In an embodiment of the present invention, at least some of the plurality of first pads are connected to each other.

In an embodiment of the present invention, the display panel further includes at least one third dummy pad adjacent to the first alignment pad and spaced apart from the first alignment pad and the plurality of first pads.

According to an embodiment of the present invention, an electronic device includes: a processor; a memory having stored application programs for execution by the processor; a display device, includes: a display panel; and a circuit film electrically connected to the display panel, wherein the display panel includes: a plurality of first pads, wherein some of the plurality of first pads extend in a first direction, wherein the plurality of first pads are arranged in a second direction different from the first direction; and a first alignment pad including a first portion and a second portion that intersects the first portion, and wherein the circuit film includes: a plurality of second pads, wherein some of the plurality of second pads extend in the first direction, wherein the plurality of second pads are arranged in the second direction; and a second alignment pad including a first portion and a second portion that intersects the first portion; and a user interface configured to sense user input via touch or cursor select of an icon presented on the display panel, wherein the processor is caused to execute one or more of the stored application programs upon receipt of the user input.

### BRIEF DESCRIPTION OF THE DRAWINGS

The above and other aspects and features of embodiments of the present invention will be more apparent by describing in detail embodiments thereof, with reference to the accompanying drawings, in which:

FIG. 1 is a schematic plan view of an electronic device according to an embodiment of the present invention;

FIG. 2 is a schematic plan view of a display device according to an embodiment of the present invention;

FIG. 3 is a schematic circuit diagram of a light-emitting diode provided in a pixel of a display device and a pixel circuit connected to the light-emitting diode, according to an embodiment of the present invention;

FIG. 4 is a cross-sectional view of a portion of a display device according to an embodiment of the present invention;

FIGS. 5, 6, 7, 8, 9, and 10 are schematic plan views of a portion of a display panel and a portion of a circuit film of a display device, according to embodiments of the present invention;

FIG. 11 is a schematic cross-sectional view of a portion of a display device according to an embodiment of the present invention;

FIG. 12 is a schematic cross-sectional view of a portion of a display device according to an embodiment of the present invention;

FIG. 13 is a diagram illustrating an electronic device according to an embodiment of the present invention.

### DETAILED DESCRIPTION OF THE EMBODIMENTS

Embodiments of the present invention will now be described more fully with reference to the accompanying drawings. It is to be understood that the present invention may be embodied in different forms and thus should not be construed as being limited to the embodiments set forth herein. It is to be understood that like reference numerals may refer to like elements throughout the specification, and thus, redundant descriptions may be omitted. As used herein, the term "and/or" includes any and all combinations of one or more of the associated listed items. Throughout the disclosure, the expression "at least one of a, b or c" indicates only a, only b, only c, both a and b, both a and c, both b and c, all of a, b, and c, or variations thereof.

It will be understood that, although the terms "first", "second", etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the spirit and scope of the present invention.

The singular forms "a," "an," and "the" as used herein are intended to include the plural forms as well unless the context clearly indicates otherwise.

It will be understood that when an element or layer is referred to as being “on” another element or layer, the element or layer may be directly on another element or layer or intervening elements or layers.

In the drawings, various thicknesses, lengths, and angles are shown and while the arrangement shown does indeed represent an embodiment of the present invention, it is to be understood that modifications of the various thicknesses, lengths, and angles may be possible within the spirit and scope of the present invention and the present invention is not necessarily limited to the particular thicknesses, lengths, and angles shown.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

In the case where a certain embodiment may be implemented differently, a specific process order may be performed in the order different from the described order. As an example, two processes successively described may be performed substantially at the same time or performed in the opposite order.

Embodiments of the present invention relate to a display device that includes a display panel with a circuit film for electrical connectivity. The display panel may include a substrate including a display area and a peripheral area. The display area may include pixels controlled by thin-film transistors (TFTs) and pixel electrodes, while the peripheral area may accommodate various circuit components like drivers and controllers. To address issues with uneven pressure distribution during assembly, embodiments of the present invention include alignment pads on both the display panel and the circuit film. These pads may provide precise alignment and uniform pressure distribution, thereby increasing electrical connections.

Embodiments of the present invention may include an arrangement of first and second pads on the display panel and circuit film, respectively. These pads extend in a first direction and are arranged in a second direction to increase electrical connectivity. Alignment pads with overlapping portions further ensure that connections between the display panel and circuit film remain stable during manufacturing. The design may minimize risks of misalignment and electrical failure, which are common in conventional assembly methods.

The display device, according to an embodiment of the present invention, may be incorporated into various electronic device such as smartphones, televisions, wearable devices, and automotive displays.

According to embodiments of the present invention, the manufacturing method may involve precise alignment of the display panel and circuit film, using alignment pads to guide the process. By applying uniform pressure during assembly, the method may prevent damage to the electrical components and ensure robust connectivity. Additional features, like dummy pads and varied pad dimensions may increase alignment accuracy and further increase device reliability.

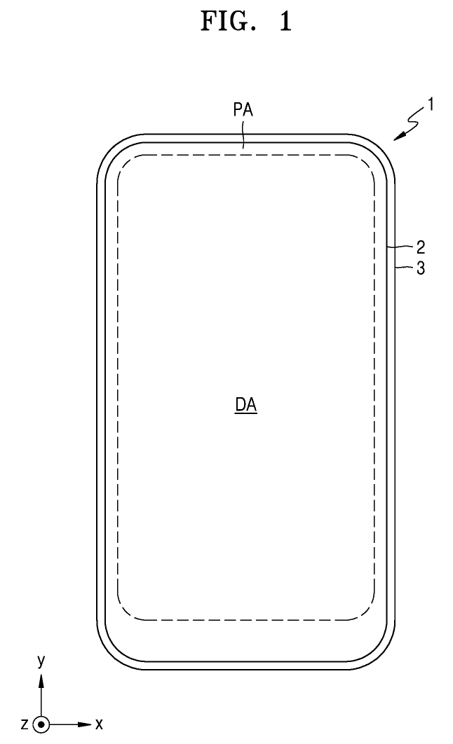

FIG. 1 is a schematic plan view of an electronic device 1 according to an embodiment of the present invention.

The electronic device 1 may include a display device 2 and a housing 3. In an embodiment of the present invention, the display device 2 may be accommodated in the housing 3.

The electronic device 1 may include various products including televisions, notebook computers, monitors, advertisement boards, Internet of things (IoTs) devices as well as portable electronic devices including mobile phones, smartphones, tablet personal computers (PCs), mobile communication terminals, electronic organizers, electronic books, portable multimedia players (PMPs), navigations, and ultra mobile personal computers (UMPCs). In addition, the electronic device 1 according to an embodiment of the present invention may include wearable devices including smartwatches, watchphones, glasses-type displays, and head-mounted displays (HMDs). In addition, in an embodiment of the present invention, electronic device 1 may include a display screen in instrument panels for automobiles, center fascias for automobiles, or center information displays (CIDs) arranged on a dashboard, mirror displays that replace side mirrors of automobiles, and displays of an entertainment system arranged on the backside of front seats for backseat passengers in automobiles. The display device 2 may be included in the electronic device 1 as an element for displaying moving images or still images in various embodiments of the electronic devices 1. Although it is shown in FIG. 1 that the electronic device 1 is a smartphone, the disclosure is not limited thereto and this is merely an example.

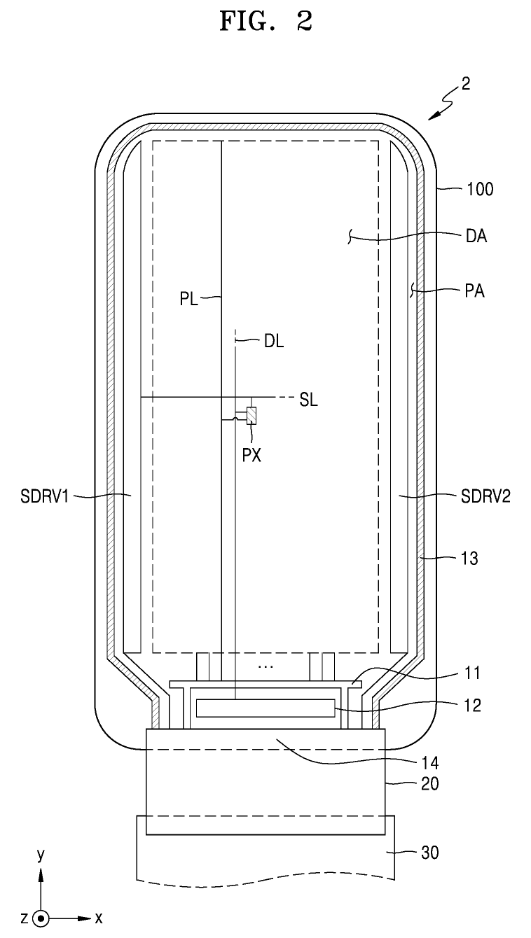

The display device 2 may include a display area DA and a peripheral area PA outside the display area DA. Because the display device 2 includes a substrate 100 (see FIG. 2), it may be understood that the substrate 100 includes the display area DA and the peripheral area PA. In addition, it may be understood that the display area DA and the peripheral area PA are defined in the substrate 100.

The display area DA is a region in which images are displayed, and a plurality of pixels may be disposed in the display area DA. The display area DA may have various shapes, for example, circular shapes, elliptical shapes, polygonal shapes, or shapes of specific figures. It is shown as an example in FIG. 1 that the display area DA has an approximately rectangular shape having round corners. However, the present invention is not limited thereto, and the rectangular shape may have corners that are ninety degrees.

The peripheral area PA may be disposed outside the display area DA. The peripheral area PA may be disposed to surround at least a portion of the display area DA.

Hereinafter, although an organic light-emitting display device is described as an example of the display device 1 according to an embodiment of the present invention, the display device according to the disclosure is not limited thereto. In an embodiment of the present invention, the display device 2 according to an embodiment of the present invention may be an inorganic light-emitting display device or a quantum-dot light-emitting display device. As an example, an emission layer of a display element provided in the display device 2 may include an organic material, an inorganic material, quantum dots, an organic material and quantum dots, or an inorganic material and quantum dots.

FIG. 2 is a schematic plan view of the display device 2 according to an embodiment of the present invention.

Referring to FIG. 2, the display device 2 may include a display panel 10, a circuit film 20, and a printed circuit board 30. The circuit film 20 may connect the display panel 10 and the printed circuit board 30 to each other.

The display panel 10 may include the substrate 100. Various types of elements constituting the display device 2 may be disposed on the substrate 100. The substrate 100 includes the display area DA and the peripheral area PA outside the display area DA. In the present specification, when a preset element is located in the display area DA, it means that the element is disposed in the display area DA of the substrate 100, or disposed to overlap the display area DA. Similarly, in the present specification, when a preset element is located in the peripheral area PA, it means that the element is disposed in the peripheral area PA of the substrate 100, or disposed to overlap the peripheral area PA.

A plurality of pixels PX may be disposed in the display area DA. Each of the pixels PX may be implemented by a light-emitting diode such as an organic light-emitting diode. Each pixel PX may emit, for example, red, green, blue, or white light. In the present specification, it may be understood that a term "pixel" includes a plurality of grouped "sub-pixels" to constitute one pixel (e.g., a pixel unit).

Pixel circuits driving the pixels PX may each be connected to a signal line or a voltage line configured to control turning-on/off, brightness, and the like of a light-emitting diode. As an example, FIG. 2 shows a scan line SL extending in one direction (e.g., an x axis direction), a data line DL extending in another direction (e.g., a y axis direction), and a driving voltage line PL as a voltage line.

The peripheral area PA may be a non-display area in which images are not displayed. The peripheral area PA may at least partially surround the display area DA. For example, the peripheral area PA may completely surround the display area DA. The peripheral area PA may include outer circuits for driving the pixels PX. As an example, a first scan driver SDRV1, a second scan driver SDRV2, a driving voltage supply line 11, a data driver 12, a common voltage supply line 13, and a terminal part 14 may be disposed in the peripheral area PA.

The first scan driver SDRV1 may be configured to apply scan signals to each of pixel circuits through the scan lines SL, the pixel circuits being configured to drive the pixels PX. The second scan driver SDRV2 may be disposed opposite the first scan driver SDRV1 with the display area DA therebetween, and be approximately parallel to the first scan driver SDRV1. Some of the pixels PX disposed in the display area DA may be electrically connected to the first scan driver SDRV1, and others may be electrically connected to the second scan driver SDRV2.

The data driver 12 may include an integrated circuit (e.g., a driving chip) that drives the display panel 10. Although the integrated circuit may be a data driving integrated circuit configured to generate data signals, the present invention is not limited thereto. The data driver 12 may include a plurality of terminals. The data driver 12 may be electrically connected to the printed circuit board 30 through terminals. For example, the data driver 12 may be electrically connected to circuit film 20 through the terminals, and the circuit film 20 may be electrically connected to the printed circuit board 30. In an embodiment, the data driver 12 may be provided on the printed circuit board 30.

The terminal part 14 of the display panel 10 may overlap the circuit film 20. A portion of the terminal part 14 of the display panel 10 may be exposed by not being covered by an insulating layer. As described below, the display panel 10 may be electrically connected to the circuit film 20 through pads that are provided on the terminal part 14 and pads that are provided on the circuit film 20. As an example, the pads of the terminal part 14 of the display panel 10 and the pads of circuit film 20 may be in contact with each other, and the display panel 10 may be electrically connected to the circuit film 20 through the pads of the terminal part 14 and the pads of the circuit film 20. In a similar method, the circuit film 20 may be electrically connected to the printed circuit board 30. Through this, the display panel 10 may be electrically connected to the printed circuit board 30. A circuit may be provided in the circuit film 20, and the circuit may electrically connect the display panel 10 to the printed circuit board 30.

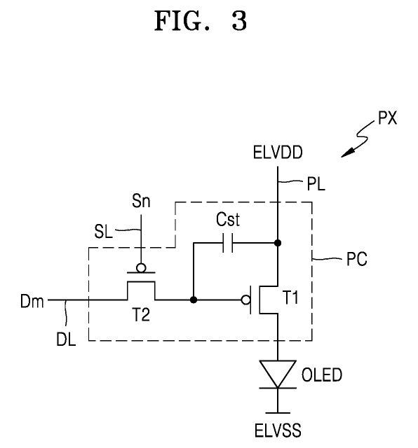

A controller may be disposed on the printed circuit board 30. The controller may be configured to generate control signals transferred to the first scan driver SDRV1 and the second scan driver SDRV2. The controller may be configured to supply a driving voltage ELVDD (see FIG. 3) to the driving voltage supply line 11 and supply a common voltage ELVSS (see FIG. 3) to the common voltage supply line 13. The driving voltage ELVDD (see FIG. 3) may be applied to the pixel circuits of the pixels PX through the driving voltage line PL connected to the driving voltage supply line 11, and the common voltage ELVSS (see FIG. 3) may be applied to an opposite electrode of a light-emitting diode connected to the common voltage supply line 13. The driving voltage supply line 11 may extend in one direction (e.g., the x axis direction) below the display area DA. The common voltage supply line 13 may extend to have a loop shape with one open side to partially surround the display area DA.

The controller may generate a data signal, and the generated data signal may be transferred to the data line DL through the data driver 12. The controller may sequentially transfer data signals to the pixels PX, which are located in the same column as each other, through the data lines DL extending in one direction (e.g., a y direction).

FIG. 3 is a schematic circuit diagram of a light-emitting diode provided in a pixel PX of the display device 2 and a pixel circuit PC connected to the light-emitting diode according to an embodiment of the present invention.

Referring to FIG. 3, the pixel circuit PC may be connected to a light-emitting diode such as an organic light-emitting diode OLED to implement light emission of the pixels PX. The pixel circuit PC may include a first transistor T1, a second transistor T2, and a storage capacitor Cst. In an embodiment of the present invention, the first transistor T1 may be a driving transistor, and the second transistor T2 may be a switching transistor. The second transistor T2 is connected to the scan line SL and the data line DL, and configured to transfer a data signal Dm to the first transistor T1 according to a scan signal Sn. The data signal Dm is input through the data line DL, and the scan signal Sn is input through the scan line SL.

The storage capacitor Cst may be connected to the second transistor T2 and the driving voltage line PL and configured to store a voltage corresponding to a difference between a voltage transferred from the second transistor T2 and the driving voltage ELVDD supplied to the driving voltage line PL.

The first transistor T1 may be connected to the driving voltage line PL and the storage capacitor Cst and configured to control a driving current according to the voltage stored in the storage capacitor Cst, and the driving current flows from the driving voltage line PL to the organic light-emitting diode OLED. The organic light-emitting diode OLED may be configured to emit light having a preset brightness corresponding to the driving current.

The pixel circuit PC is not limited to the number of thin-film transistors, the number of storage capacitors, and the circuit design described with reference to FIG. 3, and the number of thin-film transistors, the number of storage capacitors, and the circuit design may be variously changed.

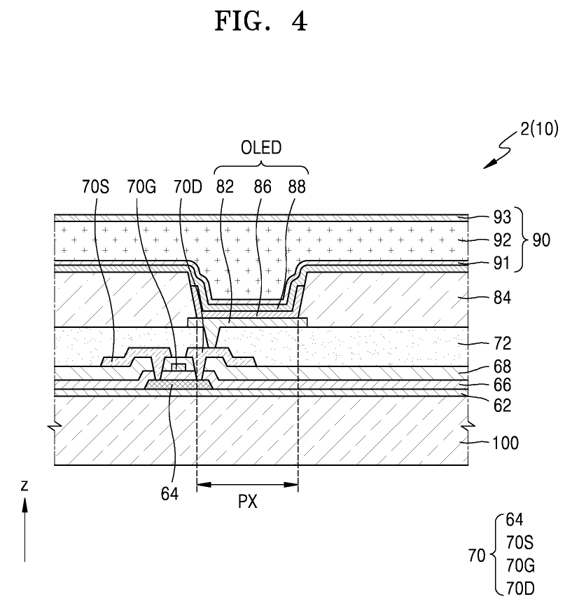

FIG. 4 is a cross-sectional view of a portion of the display device 2 according to an embodiment of the present inventive concept. FIG. 4 may be a cross-sectional view of a portion of the display panel 10 according to an embodiment of the present invention.

Referring to FIG. 4, the display panel 10 may include, for example, the organic light-emitting diode OLED as a light-emitting element. However, the present invention is not limited thereto, and the display device 2 may include other light-emitting devices such as a liquid crystal display and electrophoretic display as a light-emitting element.

A buffer layer 62 may be disposed on the substrate 100. The buffer layer 62 may include an inorganic material such as silicon oxide (SiO₂), silicon nitride (SiN_{X}), and/or silicon oxynitride (SiON). The buffer layer 62 may increase a smoothness of the upper surface of the substrate 100 and/or prevent or reduce impurities from penetrating an active layer 64 of a thin-film transistor 70 from the substrate 100. In an embodiment of the present invention, the buffer layer 62 may be omitted.

The thin-film transistor 70 may be disposed over the substrate 100. For example, the thin-film transistor 70 may be disposed on the buffer layer 62. The thin-film transistor 70 may be electrically connected to a pixel electrode 82. The thin-film transistor 70 may include an active layer 64, a gate electrode 70G, a source electrode 70S, and a drain electrode 70D. The active layer 64 may include a semiconductor material such as amorphous silicon, polycrystalline silicon, an oxide semiconductor material or an organic semiconductor. The gate electrode 70G may be insulated from the active layer 64. Each of the source electrode 70S and the drain electrode 70D may be electrically connected to the active layer 64. The gate electrode 70G may be disposed over the active layer 64, and the source electrode 70S and the drain electrode 70D may be electrically communicated with each other according to a signal applied to the gate electrode 70G. For example, the gate electrode 70G may include at least one of aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu), and include a single layer or a multi-layer by, for example, taking into account adhesion with adjacent layers, surface flatness of stacked layers, workability, and the like.

For insulation between the active layer 64 and the gate electrode 70G, a first insulating layer 66 may be disposed between the active layer 64 and the gate electrode 70G. The first insulating layer 66 may include an inorganic material such as silicon oxide (SiO₂), silicon nitride (SiN_{X}), and/or silicon oxynitride (SiON). A second insulating layer 68 may be disposed on the gate electrode 70G, and the source electrode 70S and the drain electrode 70D may be disposed on the second insulating layer 68. The source electrode 70S and the drain electrode 70D may be respectively electrically connected to source and drain areas of the active layer 64 through contact holes formed in the first insulating layer 66 and the second insulating layer 68. The second insulating layer 68 may include an inorganic material such as silicon oxide (SiO₂), silicon nitride (SiN_{X}), and/or silicon oxynitride (SiON).

A third insulating layer 72 may be disposed on the thin-film transistor 70, and the third insulating layer 72 covers the thin-film transistor 70. The third insulating layer 72 may have a flat upper surface such that the pixel electrode 82 is formed flat. For example, the third insulating layer 72 may be a planarization layer. The third insulating layer 72 may include an organic material such as acryl, benzocyclobutene (BCB), polyimide (PI), or hexamethyldisiloxane (HMDSO). Although it is shown in FIG. 4 that the third insulating layer 72 is a single layer, the third insulating layer 72 may be a multi-layer.

The third insulating layer 72 may include a via hole exposing one of the source electrode 70S or the drain electrode 70D of the thin-film transistor 70. The pixel electrode 82 may be electrically connected to the thin-film transistor 70 by being in contact with one of the source electrode 70S and the drain electrode70D through the via hole. As an example, it is shown in FIG. 4 that the pixel electrode 82 is connected to the drain electrode 70D.

The organic light-emitting diode OLED may be disposed on the third insulating layer 72, and the organic light-emitting diode OLED includes the pixel electrode 82, an intermediate layer 86 disposed on the pixel electrode 82, and an opposite electrode 88 disposed on the intermediate layer 86. The intermediate layer 86 may include an emission layer.

In an embodiment of the present invention, the pixel electrode 82 may include a reflective electrode. In the case where the pixel electrode 82 includes a reflective electrode, the pixel electrode 82 may include a reflective layer and a transparent conductive layer disposed on and/or under the reflective layer, and the reflective layer may include, for example, at least one of silver (Ag), magnesium (Mg), aluminum (Al), platinum (Pt), palladium (Pd), gold (Au), nickel (Ni), neodymium (Nd), iridium (Ir), chrome (Cr), or a compound thereof. The transparent conductive layer may include at least one selected from among indium tin oxide (ITO), indium zinc oxide (IZO), zinc oxide (ZnO), indium oxide (In₂O₃), indium gallium oxide (IGO), and/or aluminum-zinc oxide (AZO). However, the present invention is not limited thereto and the pixel electrode 82 may include various materials, and the structure thereof may be a single layer or a multi-layer and be variously modified.

A pixel-defining layer 84 may be disposed on the third insulating layer 72, and the pixel-defining layer 84 covers edge regions of the pixel electrode 82. The pixel-defining layer 84 includes an opening exposing a portion of the pixel electrode 82 and may define a pixel. For example, the opening may correspond to an emission region of the pixel. The pixel-defining layer 84 may include an organic material such as PI or HMDSO. The pixel-defining layer 84 may include a single layer or a multi-layer.

The intermediate layer 86 may be disposed on the central portion of the pixel electrode 82 that is exposed by the pixel-defining layer 84. The intermediate layer 86 may include an emission layer (EML), and in addition, may further include functional layers such as a hole injection layer (HIL), a hole transport layer (HTL), an electron transport layer (ETL), and/or an electron injection layer (EIL).

The structure of the intermediate layer 86 is not necessarily limited thereto and may have various structures. In addition, the intermediate layer 86 may include an integral layer over a plurality of pixel electrodes 82, or include a layer patterned to correspond to each of the plurality of pixel electrodes 82.

The opposite electrode 88 may be disposed on the intermediate layer 86. Unlike the pixel electrode 82, the opposite electrode 88 may be integrally formed over the plurality of pixels PX. For example, the opposite electrode 88 may be a common electrode that is disposed over the plurality of pixels PX.

The opposite electrode 88 may include a transparent or semi-transparent electrode. In the case where the opposite electrode 88 includes a transparent or semi-transparent electrode, the opposite electrode 88 may include a thin-film including at least one of silver (Ag), aluminum (Al), magnesium (Mg), lithium (Li), calcium (Ca), copper (Cu), lithium/calcium fluoride (LiF/Ca), lithium/aluminum fluoride (LiF/Al), magnesium-silver alloy (MgAg), and/or calcium-silver alloy (CaAg). The construction and material of the opposite electrode 88 are not limited thereto and may be variously modified.

A thin-film encapsulation layer 90 may be disposed on the opposite electrode 88. The thin-film encapsulation layer 90 encapsulates the organic light-emitting diode OLED such that the organic light-emitting diode OLED is not exposed to an external environment (e.g., external air) or a foreign substance. Because the thin-film encapsulation layer 90 has a very thin thickness, the thin-film encapsulation layer 90 may be used as a sealing means of a flexible display device that is bendable or foldable.

The thin-film encapsulation layer 90 may include a first inorganic encapsulation layer 91, an organic encapsulation layer 92, and a second inorganic encapsulation layer 93 sequentially disposed on the opposite electrode 88. The first inorganic encapsulation layer 91 may include, for example, silicon oxide (SiO₂), silicon nitride (SiN_{X}), and/or silicon oxynitride (SiON). Because the first inorganic encapsulation layer 91 is formed along a structure thereunder, an upper surface thereof might not be flat. The organic encapsulation layer 92 covers the first inorganic encapsulation layer 91 and may form a flat upper surface. The organic encapsulation layer 92 may include at least one of, example, polyethylene terephthalate, polyethylene naphthalate, polycarbonate, polyimide, polyethylene sulfonate, polyoxymethylene, and polyarylate, hexamethyldisiloxane. The second inorganic encapsulation layer 93 may cover the organic encapsulation layer 92 and may include silicon oxide (SiO₂), silicon nitride (SiNₓ), and/or silicon oxynitride (SiON). Although it is shown in FIG. 4 that the thin-film encapsulation layer 90 includes one organic encapsulation layer 92, the thin-film encapsulation layer 90 may have a structure in which a plurality of organic encapsulation layers and inorganic encapsulation layers are alternately stacked on the organic light emitting diode OLED.

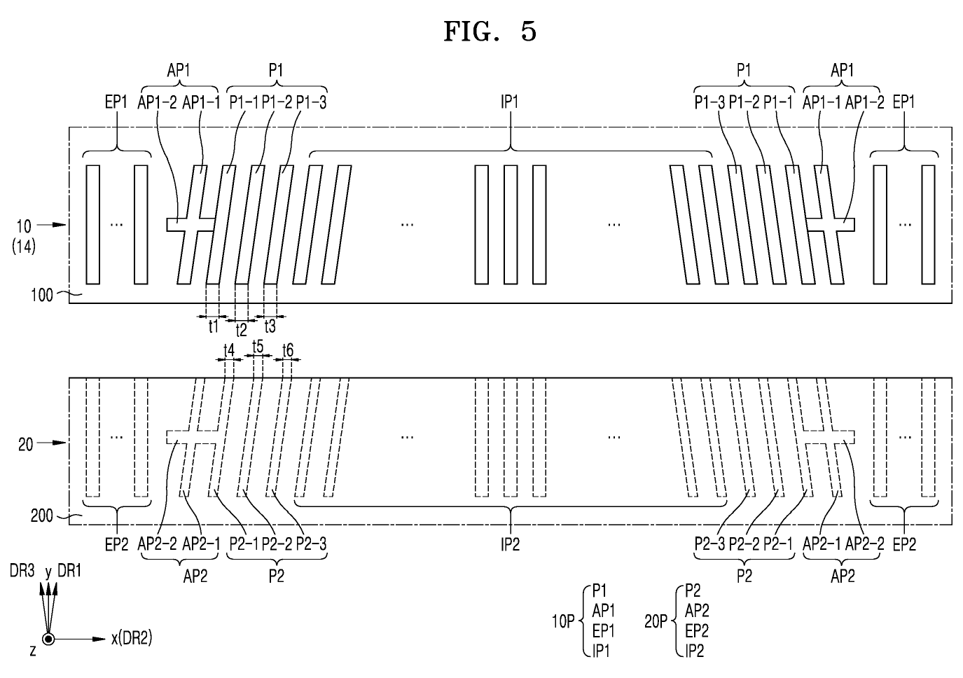

FIGS. 5, 6, 7, 8, 9, and 10 are schematic plan views of a portion of the display panel 10 and a portion of the circuit film 20 of the display device 2 according to embodiments of the present invention.

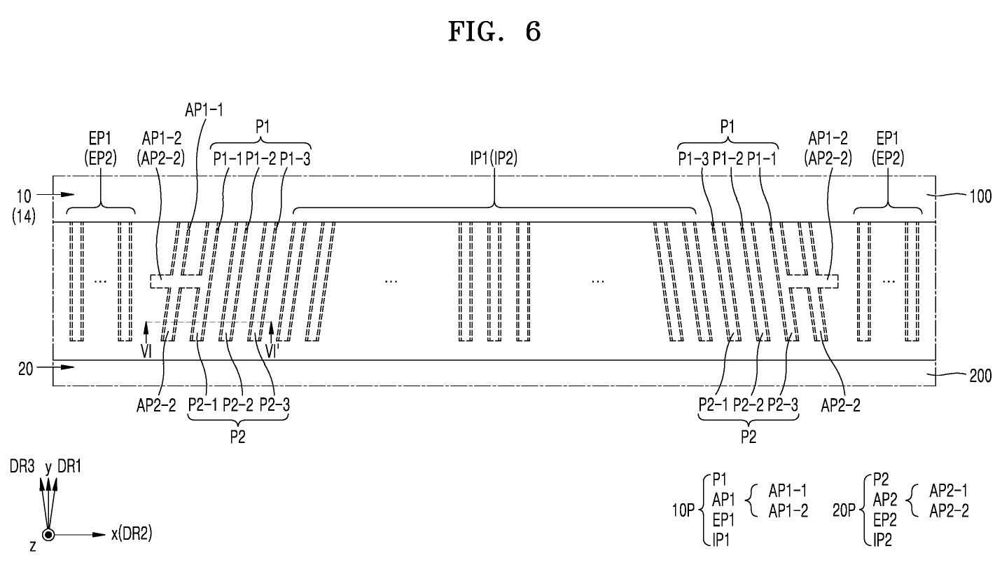

As an example, FIGS. 5 to 10 schematically show the terminal part 14 of the display panel 10 and a portion of the circuit film 20 overlapping the terminal part 14. FIGS. 5, 7, 8, 9, and 10 show the display panel 10 and circuit film 20 separately for convenience of explanation. FIG. 6 shows a state in which the display panel 10 overlaps the circuit film 20. FIG. 6 shows an embodiment in which the display panel 10 of the embodiment shown in FIG. 5 overlaps the circuit film 20.

In the display device 2 (see FIG. 2) according to an embodiment of the present invention, as shown in FIGS. 2 and 6, the display panel 10 overlaps the circuit film 20, and it should be noted that in FIGS. 5, 7, 8, 9, and 10, the display panel 10 and the circuit film 20 are separated for convenience of description.

Pads 10P of the display panel 10 may be disposed on the substrate 100, and pads 20P of the circuit film 20 may be disposed on a film 200. In the present specification, when the pads 10P of the display panel 10 are disposed on the substrate 100, it may be understood that the pads 10P of the display panel 10 are disposed on a surface of the substrate 100 facing a z axis direction. In the present specification, when the pads 20P of the circuit film 20 are disposed on the film 200, it may be understood that the pads 20P of the circuit film 20 are disposed on a surface of the film 200 facing an opposite direction of the z axis direction (e.g., a -z axis direction). Accordingly, the pads 10P of the display panel 10 and the pads 20P of the circuit film 20 may face each other. When the display panel 10 and the circuit film 20 overlap each other, the pads 10P of the display panel 10 and the pads 20P of the circuit film 20 may be brought into contact with each other. The pads 10P of the display panel 10 and the pads 20P of the circuit film 20 may include a conductive material (e.g., metal).

Referring to FIGS. 5 and 6, the pads 10P of the display panel 10 may include a plurality of first pads P1, a plurality of first alignment pads AP1, a plurality of first external pads EP1, and a plurality of first inner pads IP1. In a direction from the central portion to the outer side of the display panel 10, the plurality of first inner pads IP1, the plurality of first pads P1, the plurality of first alignment pads AP1, and the plurality of first external pads EP1 may be sequentially disposed. For example, the plurality of first inner pads IP1, the plurality of first pads P1, the plurality of first alignment pads AP1, and the plurality of first external pads EP1 may be symmetrically disposed with respect to the central portion of the substrate 100. Hereinafter, the pads 10P disposed on the left (that is, in the opposite direction of the x axis direction) with respect to the central portion of the substrate 100 are mainly described. The following characteristics are also applicable to the pads 10P disposed on the right (that is, in the x axis direction) with respect to the central portion of the substrate 100.

The plurality of first inner pads IP1 may extend in one direction and arranged in a different direction. As an example, some of the plurality of first inner pads IP1 may extend in a first direction DR1 and be arranged in a second direction DR2 (that is, the x axis direction (e.g., the -x axis direction)). The first direction DR1 may be a direction forming a preset angle with respect to the x axis direction and/or a y axis direction. For example, the first direction DR1 may extend between the x axis direction and the y axis direction. For example, some of the plurality of first inner pads IP1 may be slanted. Others of the plurality of first inner pads IP1 may extend in a third direction DR3 and be arranged in the second direction DR2. The third direction DR3 may be an arbitrary direction forming a preset angle with respect to the x axis direction and/or the y axis direction. For example, the third direction DR3 may extend between the -x axis and the y axis. Some of the plurality of first inner pads IP1, for example, some first inner pads IP1 close to the central portion of the substrate 100 may extend in the y axis. In an embodiment of the present invention, the first direction DR1 and the third direction DR3 may be symmetrical to each other with respect to the y axis.

In an embodiment of the present invention, the plurality of first inner pads IP1 may be pads transmitting and/or receiving signals to/from the PCB 30 (see FIG. 2) through the circuit film 20.

The plurality of first pads P1 may be disposed adjacent to the plurality of first inner pads IP1. Similar to the plurality of first inner pads IP1, the plurality of first pads P1 may extend in the first direction DR1 or the third direction DR3. The plurality of first pads P1 may be arranged in the second direction DR2. For example, some of the plurality of first pads P1 may be parallel to some of the plurality of first inner pads IP1. In an embodiment of the present invention, the plurality of first pads P1 may include a first-1 pad P1-1, a first-2 pad P1-2, and a first-3 pad P1-3. The first-1 pad P1-1 may be adjacent to the first alignment pad AP1 of the plurality of first alignment pads AP1, and the first-3 pad P1-3 may be adjacent to the plurality of first inner pads IP1. The first-2 pad P1-2 may be disposed between the first-1 pad P1-1 and the first-3 pad P1-3. However, this is just an example, and the present invention is not limited to a preset number of plurality of first pads P1.

In an embodiment of the present invention, the plurality of first pads P1 may be used to measure a resistance of the pads 10P of the display panel 10.

The plurality of first alignment pads AP1 may include one first alignment pad AP1 on the left side of the center portion of the substrate 100 and one first alignment pad AP1 on the right side of the center portion of the substrate 100. The first alignment pad AP1 may have a cross shape that is inclined. As an example, the first alignment pad AP1 may have a first portion AP1-1 and a second portion AP1-2 crossing each other. The first portion AP1-1 of the first alignment pad AP1 may extend in the first direction DR1 or third direction DR3. For example, the first portion AP1-1 of the first alignment pad AP1 and some of the plurality of first pads P1 may be parallel to each other. The second portion AP1-2 of the first alignment pad AP1 may extend in the second direction DR2. The second portion AP1-2 of the first alignment pad AP1 may be adjacent to the first-1 pad P1-1. For example, the second portion AP1-2 of the first alignment pad AP1 may be in contact with the first-1 pad P1-1. In addition, according to an embodiment of the present invention, the second portion AP1-2 of the first alignment pad AP1 may be integrally formed with the first-1 pad P1-1. In an embodiment of the present invention, a length of the first portion AP1-1 of the first alignment pad AP1 in the first direction DR1 or third direction DR3 may be equal to a length of the plurality of first pads P1 in the first direction DR1 or third direction DR3. In addition, the length of the first portion AP1-1 of the first alignment pad AP1 in the first direction DR1 or the third direction DR3 is different from a length of the second portion AP1-2 of the first alignment pad AP1 in the second direction DR2. For example, the length of the first portion AP1-1 of the first alignment pad AP1 in the first direction DR1 or the third direction DR3 maybe larger than a length of the second portion AP1-2 of the first alignment pad AP1 in the second direction DR2.

In an embodiment of the present invention, the plurality of first alignment pads AP1 may be used to align the display panel 10 and the circuit film 20. As an example, to align the display panel 10 and the circuit film 20, the plurality of first alignment pads AP1 may be aligned with the plurality of second alignment pads AP2. For example, to respectively align the plurality of first external pads EP1, first pads P1, and first inner pads IP1 of the display panel 10 with the plurality of second external pads EP2, second pads P2, and second inner pads IP2 of the circuit film 20, the plurality of first alignment pads AP1 may be aligned with the plurality of second alignment pads AP2.

The plurality of first external pads EP1 may extend in the y axis direction. The plurality of first external pads EP1 may be arranged in the second direction DR2.

In an embodiment of the present invention, the plurality of first external pads EP1 may be inspection pads used to inspect the display panel 10.

In an embodiment of the present invention, lengths of the plurality of first inner pads IP1, the plurality of first pads P1, and the first portion AP1-1 of the plurality of first alignment pads AP1 in the first direction DR1 or third direction DR3 may be the same. In an embodiment of the present invention, lengths of the plurality of first inner pads IP1, the plurality of first pads P1, the first portion AP1-1 of the plurality of first alignment pads AP1, and the plurality of first external pads EP1 in the y axis direction may be the same.

Similarly, the pads 20P of the circuit film 20 may include a plurality of second pads P2, a plurality of second alignment pads AP2, a plurality of second external pads EP2, and a plurality of second inner pads IP2. In a direction from the central portion to the outer side of the circuit film 20, the plurality of second inner pads IP2, the plurality of second pads P2, the plurality of second alignment pads AP2, and the plurality of second external pads EP2 may be sequentially disposed. For example, the plurality of second inner pads IP2, the plurality of second pads P2, the plurality of second alignment pads AP2, and the plurality of second external pads EP2 may be symmetrically disposed with respect to the central portion of the film 200. Hereinafter, the pads 20P disposed on the left (that is, in the opposite direction of the x axis direction) with respect to the central portion of the film 200 are mainly described. The following characteristics are also applicable to the pads 20P disposed on the right (that is, in the x axis direction) with respect to the central portion of the film 200.

The plurality of second inner pads IP2 may extend in one direction and be arranged in a different direction. As an example, some of the plurality of second inner pads IP2 may extend in a first direction DR1 and be arranged in a second direction DR2 (that is, the x axis direction). Others of the plurality of second inner pads IP2 may extend in a third direction DR3 and be arranged in the second direction DR2. Some of the plurality of second inner pads IP2, for example, some second inner pads IP2 close to the central portion of the film 200 may extend in the y axis direction.

In an embodiment of the present invention, the plurality of second inner pads IP2 may be pads that transfer signals between the display panel 10 and the PCB 20 (see FIG. 2).

The plurality of second pads P2 may be disposed adjacent to the plurality of second inner pads IP2. Similar to the plurality of second inner pads IP2, the plurality of second pads P2 may extend in the first direction DR1 or the third direction DR3. The plurality of second pads P2 may be arranged in the second direction DR2. For example, some of the plurality of second pads P2 may be parallel to some of the plurality of second inner pads IP2. In an embodiment of the present invention, the plurality of second pads P2 may include a second-1 pad P2-1, a second-2 pad P2-2, and a second-3 pad P2-3. The second-1 pad P2-1 may be adjacent to the second alignment pad AP2 of the plurality of first alignment pads AP1, and the second-3 pad P2-3 may be adjacent to the plurality of second inner pads IP2. The second-2 pad P2-2 may be disposed between the second-1 pad P2-1 and the second-3 pad P2-3. However, this is just an example, and the present invention is not limited to a preset number of plurality of second pads P2.

In an embodiment of the present invention, the plurality of second pads P2 may be used to measure a resistance of the pads 10P of the display panel 10.

The plurality of second alignment pads AP2 may include one second alignment pad AP2 on the left side of the center portion of the film 200 and one second alignment pad AP2 on the right side of the center portion of the film 200. The second alignment pad AP2 may have a cross shape that is inclined. As an example, the second alignment pad AP2 may have a first portion AP2-1 and a second portion AP2-2 crossing each other. The first portion AP2-1 of the second alignment pad AP2 may extend in the first direction DR1 or third direction DR3. For example, the first portion AP2-1 of the second alignment pad AP2 and some of the plurality of second pads P2 may be parallel to each other. The second portion AP2-2 of the second alignment pad AP2 may extend in the second direction DR2. The second portion AP2-2 of the second alignment pad AP2 may be adjacent to the second-1 pad P2-1. For example, the second portion AP2-2 of the second alignment pad AP2 may be in contact with the second-1 pad P2-1. In addition, according to an embodiment of the present invention, the second portion AP2-2 of the second alignment pad AP2 may be integrally formed with the second-1 pad P2-1. In an embodiment of the present invention, a length of the first portion AP2-1 of the second alignment pad AP2 in the first direction DR1 or third direction DR3 may be equal to a length of the plurality of second pads P2 in the first direction DR1 or third direction DR3. In addition, the length of the first portion AP2-1 of the second alignment pad AP2 in the first direction DR1 or the third direction DR3 is different from a length of the second portion AP2-2 of the second alignment pad AP2 in the second direction DR2. For example, the length of the first portion AP2-1 of the second alignment pad AP2 in the first direction DR1 or the third direction DR3 may be larger than a length of the second portion AP2-2 of the second alignment pad AP2 in the second direction DR2.

In an embodiment of the present invention, the plurality of second alignment pads AP2 may be used to align the display panel 10 and the circuit film 20. As an example, to align the display panel 10 and the circuit film 20, the plurality of first alignment pads AP1 may be aligned with the plurality of second alignment pads AP2. For example, the first and second alignment pads AP1 and AP2 may prevent an imbalance of pressure distribution during the assembly of the display panel 10 and the circuit film 20. This may be achieved through the parallel arrangement with the first and second pads P1 and P2, which may ensure that pressure applied during assembly is evenly distributed across the contact area. In addition, the first and second alignment pads AP1 and AP2 are designed to overlap accurately, minimizing the risk of pressure being concentrated in isolated regions and instead spreading it uniformly over the aligned surfaces.

The plurality of second external pads EP2 may extend in the y axis direction. The plurality of second external pads EP2 may be arranged in the second direction DR2.

In an embodiment of the present invention, the plurality of second external pads EP2 may be inspection pads used to inspect the display panel 10.

In an embodiment of the present invention, lengths of the plurality of second inner pads IP2, the plurality of second pads P2, and the first portion AP2-1 of the plurality of second alignment pads AP2 in the first direction DR1 or third direction DR3 may be the same. In an embodiment of the present invention, lengths of the plurality of second inner pads IP2, the plurality of second pads P2, the first portion AP2-1 of the plurality of second alignment pads AP2, and the plurality of second external pads EP2 in the y axis direction may be the same.

In an embodiment of the present invention, the pads 20P of the circuit film 20 may be in contact with one edge of the film 200. As an example, the pads 20P of the circuit film 20, that is, the plurality of second inner pads IP2, the plurality of second pads P2, the plurality of second alignment pads AP2, and the plurality of second external pads EP2 may be in contact with the edge of the film 200 in the y axis direction.

In an embodiment of the present invention, the widths of the pads 10P of the display panel 10 and the widths of the pads 20P of the circuit film 20 may be different from each other. Here, the lengths may denote the length of the pads measured in a direction in which the pads 10P of the display panel 10 and the pads 20P of the circuit film 20 are arranged, that is, the second direction DR. For example, the widths of the pads 10P of the display panel 10 may be respectively greater than the widths of the pads 20P of the circuit film 20. However, the present invention is not limited thereto.

As an example, a case of the plurality of first pads P1 and the plurality of second pads P2 is described. The first-1 pad P1-1 may have a first width t1. The first-2 pad P1-2 may have a second width t2. The first-3 pad P1-3 may have a third width t3. The second-1 pad P2-1 may have a fourth width t4. The second-2 pad P2-2 may have a fifth width t5. The second-3 pad P2-3 may have a sixth width t6. In an embodiment of the present invention, the first width t1, the second width t2, and the third width t3 may be equal to one another. In an embodiment of the present invention, the fourth width t4, the fifth width t5, and the sixth width t6 may be equal to one another. In an embodiment of the present invention, each of the first width t1, the second width t2, and the third width t3 may be greater than each of the fourth width t4, the fifth width t5, and the sixth width t6. As an example, the first width t1 may be greater than the fourth width t4, the second width t2 may be greater than the fifth width t5, and the third width t3 may be greater than the sixth width t6. Accordingly, the widths of the plurality of first pads P1 in the second direction DR2 may be respectively greater than the widths of the plurality of second pads P2 in the second direction DR2.

The above correlation is similarly applicable between other pads (e.g., EP1, AP1, and IP1) of the display panel 10 and other pads (e.g., EP2, AP2, and IP2) of the circuit film 20. Accordingly, in FIG. 6 in which the pads 10P of the display panel 10 and the pads 20P of the circuit film 20 overlap each other, it is shown that the pads 10P of the display panel 10 respectively have a shape protruding to the left and right of the pads 20P of the circuit film 20. For example, the pads 10P of the display panel 10 might not be completely covered by the pads 20P of the circuit film 20. The length of the second portion AP1-2 of the first alignment pad AP1 in the y axis direction and the length of the second portion AP2-2 of the second alignment pad AP2 in the y axis direction may be the same as each other.

Accordingly, as shown in FIG. 6, the plurality of first alignment pads AP1 and the plurality of second alignment pads AP2 may overlap each other. In addition, the plurality of first pads P1 and the plurality of second pads P2 may overlap each other and be electrically connected to each other by being in contact with each other.

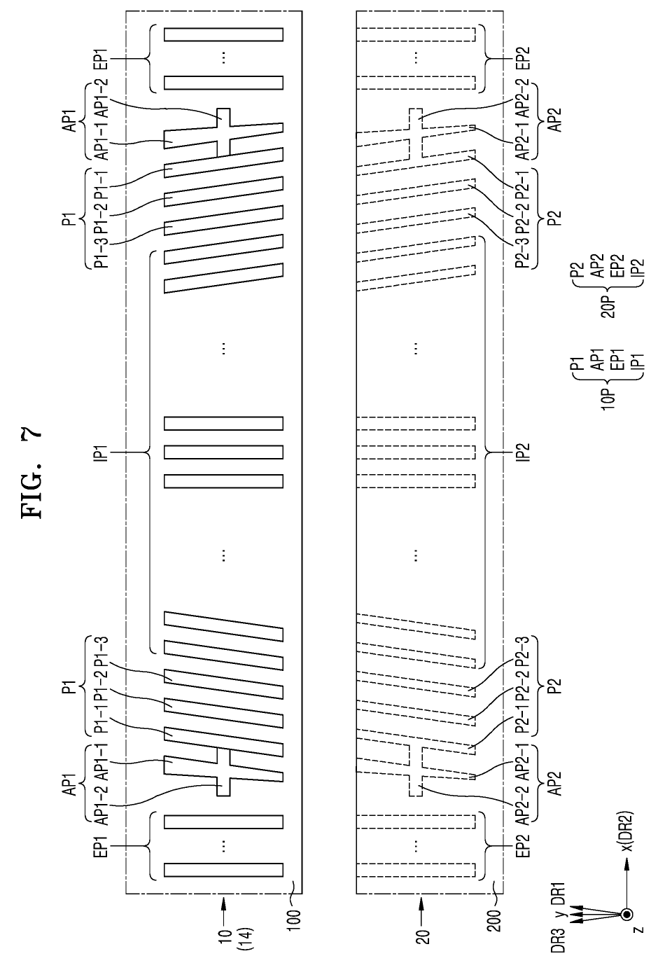

Because characteristics of an embodiment shown in FIG. 7 are substantially the same as those of the embodiment shown in FIG. 5 except for the characteristics of the first alignment pad AP1 and the second alignment pad AP2, repeated descriptions are omitted.

Referring to FIG. 7, the width (that is, the length in the second direction DR2) of the first portion AP1-1 of the first alignment pad AP1 may be different along the first direction DR1 or third direction DR3. For example, the width of the first portion AP1-1 of the first alignment pad AP1 may vary along the first direction DR1 or third direction DR3. As an example, the width of a first edge (e.g., an upper edge) of the first portion AP1-1 of the first alignment pad AP1 in the second direction DR2 may be greater than the width of a second edge (e.g., a lower edge), opposite to the first edge, of the first portion AP1-1. For example, between the first edge and the second edge, the width of the first portion AP1-1 may increase. As another example, the first portion AP1-1 may have a tapered shape. In this case, an edge adjacent to the first-1 pad P1-1 among the edges of the first portion AP1-1 of the first alignment pad AP1 may extend in the first direction DR1 or third direction DR3 and be parallel to the first-1 pad P1-1.

Similarly, the width (that is, the length in the second direction DR2) of the first portion AP2-1 of the second alignment pad AP2 may be different in the first direction DR1 or third direction DR3. In other words, the width of the first portion AP2-1 of the second alignment pad AP2 may vary along the first direction DR1 or third direction DR3. As an example, the width of a first edge (e.g. an upper edge) of the first portion AP2-1 of the second alignment pad AP2 in the second direction DR2 may be greater than the width of a second edge (e.g., a lower edge) opposite to the first edge, of the second portion AP2-2. In this case, an edge adjacent to the second-1 pad P2-1 among the edges of the first portion AP2-1 of the second alignment pad AP2 may extend in the first direction DR1 or third direction DR3 and be parallel to the second-1 pad P2-1.

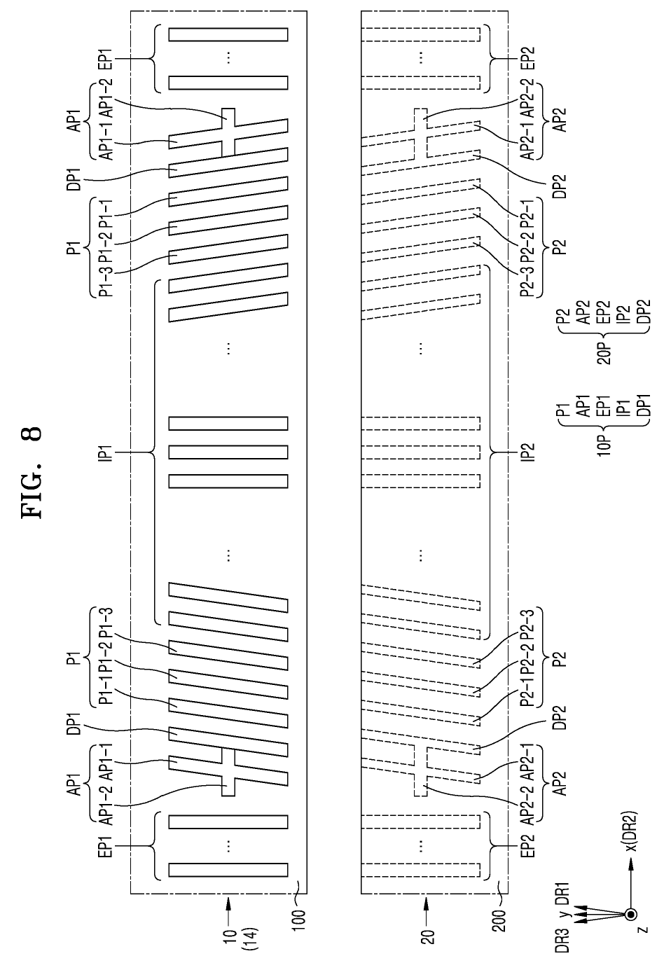

Because characteristics of an embodiment shown in FIG. 8 are substantially the same as those of the embodiment shown in FIG. 5 except for the characteristics of a first dummy pad DP1 and a second dummy pad DP2, repeated descriptions are omitted.

Referring to FIG. 8, the pads 10P of the display panel 10 may include a plurality of first dummy pads DP1. The first dummy pads DP1 may be disposed between the first alignment pad AP1 and the plurality of first pads P1. As an example, the first dummy pads DP1 may be disposed between the first alignment pad AP1 and the first-1 pad P1-1. Similar to the first alignment pad AP1 and the plurality of first pads P1, the first dummy pad DP1 may extend in the first direction DR1 or third direction DR3. In an embodiment of the present invention, the second portion AP1-2 of the first alignment pad AP1 may be adjacent to the first dummy pad DP1. In an embodiment of the present invention, the second portion AP1-2 of the first alignment pad AP1 may be in contact with the first dummy pad DP1. The entire shape of the first dummy pad DP1 may be similar to the shape of each of the plurality of first pads P1. As an example, the length of the first dummy pad DP1 in the first direction DR1 or third direction DR3 may be equal to the length of each of the plurality of first pads P1 in the first direction DR1 or third direction DR3. In addition, the length of the first dummy pad DP1 in the y axis direction may be equal to the length of each of the plurality of first pads P1 in the y axis direction.

Similarly, the pads 20P of the circuit film 20 may include a plurality of second dummy pads DP2. The second dummy pads DP2 may be disposed between the second alignment pad AP2 and the plurality of second pads P2. As an example, the second dummy pads DP2 may be disposed between the second alignment pad AP2 and the second-1 pad P2-1. Similar to the second alignment pad AP2 and the plurality of second pads P2, the second dummy pad DP2 may extend in the first direction DR1 or third direction DR3. In an embodiment of the present invention, the second portion AP2-2 of the second alignment pad AP2 may be adjacent to the second dummy pad DP2. In an embodiment of the present invention, the second portion AP2-2 of the second alignment pad AP2 may be in contact with the second dummy pad DP2. The entire shape of the second dummy pad DP2 may be similar to the shape of each of the plurality of second pads P2. As an example, the length of the second dummy pad DP2 in the first direction DR1 or third direction DR3 may be equal to the length of each of the plurality of second pads P2 in the first direction DR1 or third direction DR3. In addition, the length of the second dummy pad DP2 in the y axis direction may be equal to the length of each of the plurality of second pads P2 in the y axis direction.

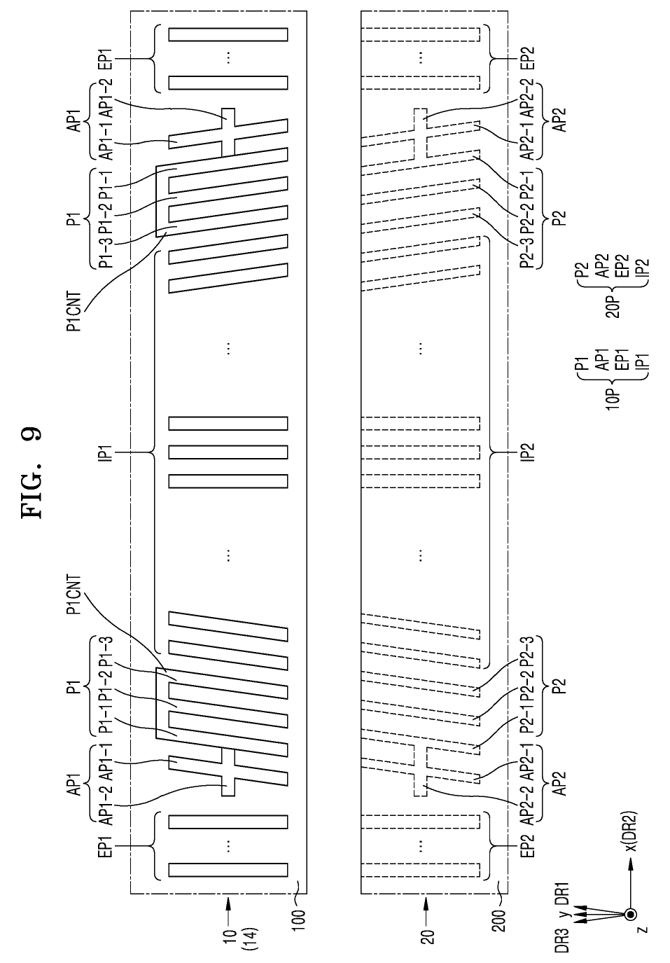

Because characteristics of an embodiment shown in FIG. 9 are substantially the same as those of the embodiment shown in FIG. 5 except for the characteristics of the first pads P1, repeated descriptions are omitted.

Referring to FIG. 9, at least some of the plurality of first pads P1 may be connected to each other. As an example, a first connector P1CNT may be disposed on the substrate 100. The first connector P1CNT may extend in the second direction DR2 and connect at least some of the first-1 pad P1-1, the first-2 pad P1-2, and the first-3 pad P1-3 to each other. Accordingly, a current may flow between the first-1 pad P1-1, the first-2 pad P1-2, and the first-3 pad P1-3.

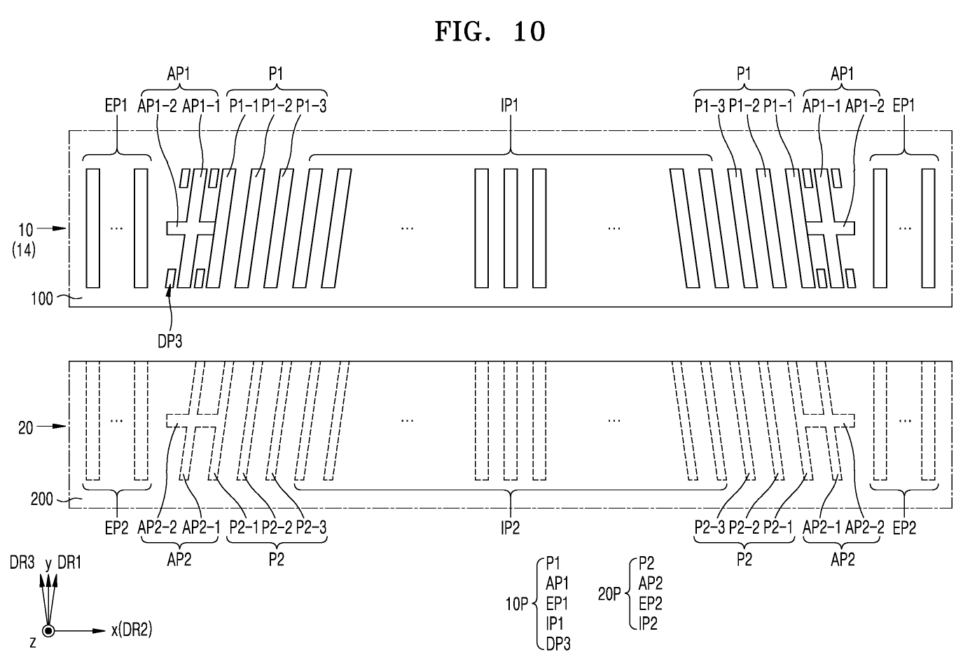

Because characteristics of an embodiment shown in FIG. 10 are substantially the same as those of the embodiment shown in FIG. 5 except for the characteristics of a third dummy pad DP3, repeated descriptions are omitted.

Referring to FIG. 10, the pads 10P of the display panel 10 may include a plurality of third dummy pads DP3. The third dummy pads DP3 may be disposed adjacent to the first alignment pad AP1. As an example, the third dummy pads DP3 may be disposed on the left and/or right of the first portion AP1-1 of the first alignment pad AP1. In addition, the third dummy pad DP3 may be disposed in the first direction DR1 and/or in the opposite direction of the first direction DR1 around the second portion AP1-2 of the first alignment pad AP1. For example, the third dummy pads DP3 may be disposed adjacent to upper and lower portions of the first portion AP1-1 of the first alignment pad AP1. As another example, the third dummy pads DP3 may be disposed adjacent to upper and lower surfaces of the second portion AP2-1. Although FIG. 10 shows a case where four third dummy pads DP3 are disposed adjacent to one first alignment pad AP1, the present invention is not necessarily limited to this number.

It would be obvious to those of ordinary skill in the art that the characteristics of the embodiments shown in FIGS. 5 to 10 may be combined.

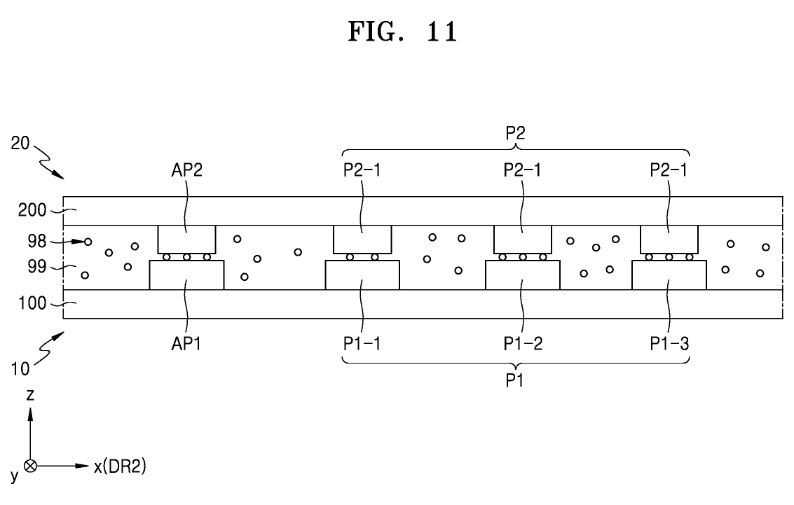

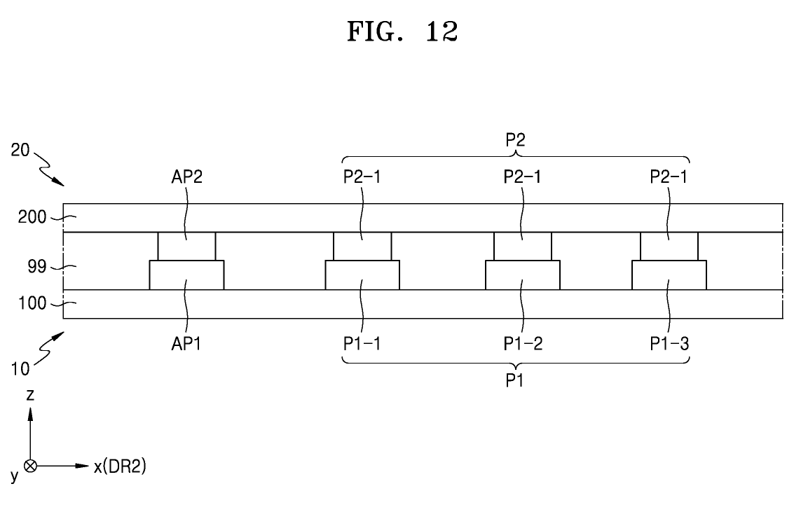

FIG. 11 is a schematic cross-sectional view of a portion of a display device according to an embodiment of the present invention. FIG. 12 is a schematic cross-sectional view of a portion of a display device according to an embodiment of the present invention. As an example, FIGS. 11 and 12 may be cross-sectional views of the display device, taken along line VI-VI' of FIG. 6.

Referring to FIGS. 6, 11, and 12 together, the pads 10P of the display panel 10 and the pads 20P of the circuit film 20 may overlap each other.

In this case, the circuit film 20 may be disposed on the display panel 10. That is, the pads 20P of the circuit film 20 may be disposed on the pads 10P of the display panel 10. However, this is just an example, and the upper and lower relationship of the display panel 10 and the circuit film 20 may be reversed.

The pads 10P of the display panel 10 and the pads 20P of the circuit film 20 may be electrically connected to each other.

In an embodiment of the present invention, as shown in FIG. 11, the pads 10P of the display panel 10 and the pads 20P of the circuit film 20 may be electrically connected to each other by being in contact with each other. As an example, the first pads P1 and the second pads P2 may be electrically connected to each other by being in contact with each other. In this case, the first-1 pad P1-1 and the second-1 pad P2-1 may be in contact with each other, the first-2 pad P1-2 and the second-2 pad P2-2 may be in contact with each other, and the first-3 pad P1-3 and the second-3 pad P2-3 may be in contact with each other. In addition, the first alignment pad AP1 and the second alignment pad AP2 may be in contact with each other. A reinforcing layer 99 may fill an empty space between the substrate 100 and the film 200. In an embodiment of the present invention, the reinforcing layer 99 may be omitted.

In an embodiment of the present invention, as shown in FIG. 12, the reinforcing layer 99 may be disposed between the substrate 100 and the film 200. A plurality of conductive balls 98 may be disposed in the reinforcing layer 99. Some of the conductive balls 98 may be disposed between the pads 10P of the display panel 10 and the pads 20P of the circuit film 20. As an example, the conductive balls 98 may be disposed between the first-1 pad P1-1 and the second-1 pad P2-1, between the first-2 pad P1-2 and the second-2 pad P2-2, and between the first-3 pad P1-3 and the second-3 pad P2-3. In addition, the conductive balls 98 may be disposed between the first alignment pad AP1 and the second alignment pad AP2. Respective pads may be electrically connected to each other through the conductive balls 98. As an example, the first-1 pad P1-1 and the second-1 pad P2-1 may be electrically connected to each other by the conductive balls 98 disposed therebetween. The second-1 pad P2-1 and the second-2 pad P2-2 may be electrically connected to each other by the conductive balls 98 disposed therebetween. The first-3 pad P1-3 and the second-3 pad P2-3 may be electrically connected to each other by the conductive balls 98 disposed therebetween.

Hereinafter, a method of manufacturing a display device according to an embodiment of the present invention is described with reference to FIGS. 5, 6, 11, and 12.

The method of manufacturing a display device according to an embodiment of the present invention may include aligning the display panel 10 and the circuit film 20, and approximating and pressing the display panel 10 and the circuit film 20 towards each other.

The embodiments shown in FIGS. 5 and 6 may be understood as an operation of aligning the display panel 10 and the circuit film 20. In this case, the display panel 10 and the circuit film 20 may be aligned with each other by aligning the plurality of first alignment pads AP1 and the plurality of second alignment pads AP2. As an example, the first portion AP1-1 of the first alignment pad AP1 and the first portion AP2-1 of the second alignment pad AP2 may be aligned with each other, and the second portion AP1-2 of the first alignment pad AP1 and the second portion AP2-2 of the second alignment pad AP2 may be aligned with each other.

The embodiments shown in FIGS. 11 and 12 may be understood as a cross-sectional view when approximating and pressing the display panel 10 and the circuit film 20. In this case, referring to FIG. 6, pressure may be induced to be uniformly distributed when applying pressure to the display panel 10 and the circuit film 20 by disposing the first alignment pad AP1 in parallel to the plurality of first pads P1 and disposing the second alignment pad AP2 in parallel to the plurality of second pads P2. Accordingly, this may reduce the issue of pressure being concentrated in some areas of the display panel 10 and circuit film 20 while other areas experience pad separation, which can occur due to a leverage effect.

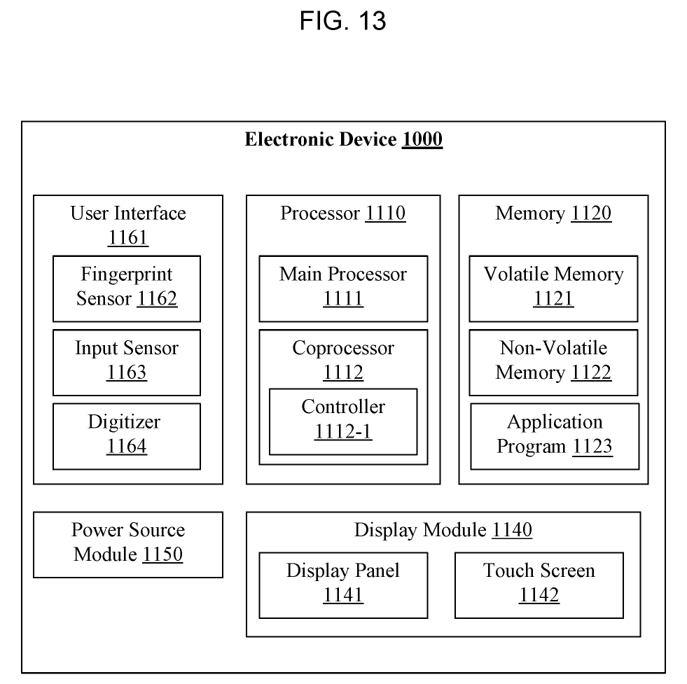

FIG. 13 is a diagram illustrating an electronic device according to an embodiment of the present invention. Referring to FIG. 13, the electronic device 1000 according to an embodiment of the present invention may output various information (e.g., images, text, music, etc.) through a display module 1140, which, for example, may correspond to the display device 2 shown in FIG. 1. When a processor 1110 executes an application stored in a memory 1120, the display module 1140 may provide application information to a user through a display panel 1141.

In some embodiments of the present invention, the electronic device 1000 may be configured as a smartphone, camera, smart TV, monitor, smartwatch, tablet, automotive display, or AR/VR headset. For example, the electronic device 1000 may be a smartphone including a touch-sensitive display area (e.g., the display area DA) for interaction and a non-display area (e.g., the peripheral area PA) including sensors and circuits for enhanced functionality. For example, the electronic device 1000 may be a television or monitor including a large display area DA for high-resolution video playback and a non-display area incorporating driving circuits or connectivity modules for external inputs. For example, the electronic device 1000 may be a smartwatch including a display area DA optimized for compact and high-clarity visuals and a non-display area integrating biometric sensors for health monitoring. In some cases, the electronic device 1000 be an AR/VR headset.

In some embodiments of the present invention, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device shown in FIG. 1.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display unit shown in FIG. 1.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

For example, the disclosure about the electronic device 1000 of FIG. 13 may be combinable with the disclosure about the electronic device 1 of FIG. 1.

According to the embodiments of the present invention, the display device, in which the pads of the display panel are parallel to the alignment pads of the display panel, and the pads of the circuit film are parallel to the alignment pads of the circuit film, and the method of manufacturing the display device are provided.

Because the pads of the display panel are provided in parallel to the alignment pads of the display panel, and the pads of the circuit film are provided in parallel to the alignment pads of the circuit film, pressure may be induced to be uniformly distributed when connecting the display panel and the circuit film to each other by applying pressure to the display panel and the circuit film. Through this, contact between the display panel and the circuit film may be improved, and further, electrical connection thereof may be improved. Additionally, this configuration may reduce the likelihood of assembly defects and may increase the overall durability and reliability of the display device.

While the present invention has been described with reference to exemplary embodiments thereof, it will be understood by those of ordinary skill in the art that various changes in form and details may be made thereto without departing from the spirit and scope of the present invention.

What is claimed is:

1. A display device comprising:
a display panel; and
a circuit film electrically connected to the display panel,
wherein the display panel comprises:
a plurality of first pads, wherein some of the plurality of first pads extend in a first direction, wherein the plurality of first pads are arranged in a second direction different from the first direction; and
a first alignment pad including a first portion extending in the first direction, and
wherein the circuit film comprises:
a plurality of second pads, wherein some of the plurality of second pads extend in the first direction, wherein the plurality of second pads are arranged in the second direction; and
a second alignment pad including a first portion extending in the first direction.

2. The display device of claim 1, wherein the first alignment pad includes a second portion crossing the first portion of the first alignment pad and extending in the second direction, and
the second alignment pad includes a second portion crossing the first portion of the second alignment pad and extending in the second direction.

3. The display device of claim 1, wherein the first alignment pad and the second alignment pad overlap each other.

4. The display device of claim 1, wherein the plurality of first pads and the plurality of second pads overlap each other and are electrically connected to each other.

5. The display device of claim 1, wherein a length of the first portion of the first alignment pad in the first direction is equal to a length of at least one of the plurality of first pads in the first direction.

6. The display device of claim 1, wherein a width of each of the plurality of first pads in the second direction is greater than a width of each of the plurality of second pads in the second direction.

7. The display device of claim 1, wherein a width of the first portion of the first alignment pad in the second direction increases along the first direction, and a width of the first portion of the second alignment pad in the second direction increases along the first direction.

8. The display device of claim 1, wherein the display panel further comprises a first dummy pad extending in the first direction and disposed between the first alignment pad and the plurality of first pads, and
the circuit film further comprises a second dummy pad extending in the first direction and disposed between the second alignment pad and the plurality of second pads, wherein the first dummy pad and the second dummy pad overlap each other.

9. The display device of claim 1, wherein at least some of the plurality of first pads are connected to each other.

10. The display device of claim 1, wherein the display panel further comprises at least one third dummy pad adjacent to the first alignment pad and spaced apart from the first alignment pad and the plurality of first pads.

11. An electronic device, comprising:
a processor;
a memory having stored application programs for execution by the processor;
a display device, comprising:
a display panel; and
a circuit film electrically connected to the display panel,
wherein the display panel comprises:
a plurality of first pads, wherein some of the plurality of first pads extend in a first direction, wherein the plurality of first pads are arranged in a second direction different from the first direction; and
a first alignment pad including a first portion and a second portion that intersects the first portion, and
wherein the circuit film comprises:
a plurality of second pads, wherein some of the plurality of second pads extend in the first direction, wherein the plurality of second pads are arranged in the second direction; and
a second alignment pad including a first portion and a second portion that intersects the first portion; and
a user interface configured to sense user input via touch or cursor select of an icon presented on the display panel, wherein the processor is caused to execute one or more of the stored application programs upon receipt of the user input.

12. A method of manufacturing a display device, the method comprising:
aligning a display panel and a circuit film with each other; and
bringing the display panel and the circuit film close to each other,
wherein the display panel comprises:
a plurality of first pads, wherein some of the plurality of first pads extend in a first direction, wherein the plurality of first pads are arranged in a second direction different from the first direction; and
a first alignment pad including a first portion extending in the first direction, and
wherein the circuit film comprises:
a plurality of second pads, wherein some of the plurality of the second pads extend in the first direction, wherein the plurality of second pads are arranged in the second direction; and
a second alignment pad including a first portion extending in the first direction,
wherein, in the aligning of the display panel and the circuit film with each other, the first alignment pad and the second alignment pad are aligned with each other.

13. The method of claim 12, wherein the first alignment pad includes a second portion crossing the first portion of the first alignment pad and extending in the second direction, and the second alignment pad includes a second portion crossing the first portion of the second alignment pad and extending in the second direction, and
in the aligning of the display panel and the circuit film with each other, the first portion and the second portion of the first alignment pad are respectively aligned with the first portion and the second portion of the second alignment pad.

14. The method of claim 12, wherein, when the first alignment pad and the second alignment pad are aligned with each other, the plurality of first pads and the plurality of second pads overlap each other.

15. The method of claim 12, wherein a length of the first portion of the first alignment pad in the first direction is equal to a length of at least one of the plurality of first pads in the first direction.

16. The method of claim 12, wherein a width of each of the plurality of first pads in the second direction is greater than a width of each of the plurality of second pads in the second direction.

17. The method of claim 12, wherein a width of the first portion of the first alignment pad in the second direction increases along the first direction, and a width of the first portion of the second alignment pad in the second direction increases along the first direction.

18. The method of claim 12, wherein the display panel further comprises a first dummy pad extending in the first direction and disposed between the first alignment pad and the plurality of first pads, and
the circuit film further comprises a second dummy pad extending in the first direction and disposed between the second alignment pad and the plurality of second pads, and
when the first alignment pad and the second alignment pad are aligned with each other, the first dummy pad and the second dummy pad overlap each other.

19. The method of claim 12, wherein at least some of the plurality of first pads are connected to each other.

20. The method of claim 12, wherein the display panel further comprises at least one third dummy pad adjacent to the first alignment pad and spaced apart from the first alignment pad and the plurality of first pads.
